(19) United States
(12) Patent Application Publication
(10) Pub. No.: US 2011/0315436 A1
(43) Pub. Date: Dec. 29, 2011

(54) Metal ink composition and method for forming the metal line using the same, and conductive pattern formed by using the metal ink composition

(75) Inventors: Tae Hoon Kim, Hwaseong-si (KR); Young Kwan Seo, Suwon-si (KR); Dong Hoon Kim, Seongnam-si (KR); Byung Ho Jun, Seoul (KR); Sung Eun Kim, Suwon-si (KR)

(73) Assignee: SAMSUNG ELECTRO-MECHANICS CO., LTD., Suwon (KR)

(21) Appl. No.: 12/923,455

(22) Filed: Sep. 22, 2010

(30) Foreign Application Priority Data
Jun. 24, 2010 (KR) 10-2010-0060073

(51) Int. Cl. H05K 1/09; H05K 3/12; H01B 1/02

(52) U.S. Cl. 174/257; 252/512; 427/98.4; 427/97.4

(57) ABSTRACT

The present invention provides a metal ink composition, which includes 20 to 80 parts by weight of cupper nano-particle; 10 to 70 parts by weight of non-aqueous organic solvent; and 2 to 20 parts by weight of additive used for adjustment of the dry speed of coated metal ink when metal lines are formed.

### CROSS-REFERENCE TO RELATED APPLICATIONS

This application claims the benefit of Korean Patent Application No. 10-2010-0060073 filed with the Korea Intellectual Property Office on Jun. 24, 2010, the disclosure of which is incorporated herein by reference.

### BACKGROUND OF THE INVENTION

1. Field of the Invention

The present invention relates to a metal ink composition and a method for forming the metal line using the same, and a conductive pattern formed by using the metal ink composition; and, more particularly, to a metal ink composition for preventing crack of the metal line and a method for forming the metal line using the metal ink composition, and a conductive pattern formed by using the metal ink composition.

2. Description of the Related Art

A noncontact direct printing technology is based on the fact that ink with a predetermined quantity can be accurately discharged on a desired position through ink-jet printing. Due to this, the noncontact direction printing technology has recently been applied to a technology for forming metal lines of fine line widths on a circuit board like a PCB.

In a process of forming metal lines through the ink-jet printing, material properties of metal ink have a significant effect on an efficiency of metal line's formation. For example, a circuit board has recently been required to have metal lines with line characteristics, as well as fine line widths, (e.g., line width of 100 μm or lower). Therefore, in order to meet this demand, there is a need to improve material properties of metal ink.

Also, in case of a conventional metal line with a fine line width, in order to meet the line characteristics, metal ink compositions are repeatedly stacked on the same position on a circuit board several times, thereby forming a metal line with a fine line width. However, in case where metal line's are formed in the repeated printing scheme as mentioned above, there have been problems such as cracking and non-uniform line widths of metal lines.

### SUMMARY OF THE INVENTION

The present invention has been proposed in order to overcome the above-described problems and it is, therefore, an object of the present invention to provide a metal ink composition and a conductive pattern formed by using the metal ink composition, by which it is possible to effectively form metal lines with fine line widths.

Further, another object of the present invention is to provide a metal ink composition and a conductive pattern formed by using the metal ink composition which can prevent occurrence of crack at the time of forming metal lines.

Further, another object of the present invention is to provide a method for manufacturing a metal ink composition which can effectively improve lines of fine line widths.

Further, another object of the present invention is to provide a method for manufacturing a metal ink composition which can prevent occurrence of crack at the time of forming metal lines.

In accordance with an aspect of the present invention to achieve the object, there is provided a metal ink composition for forming a conductive pattern including: 20 to 80 parts by weight of cupper nano-particle; 10 to 70 parts by weight of non-aqueous organic solvent; and 2 to 20 parts by weight of at least one selected from additives which include neodecanoic acid, Naphthenic acid, and Linoleic acid.

According to an embodiment of the present invention, the cupper nano-particle has a surface capped with at least one dispersant selected from fatty acid and fatty amine.

According to an embodiment of the present invention, the non-aqueous organic solvent includes at least one selected from a group consisting of hexane, octane, decane, tetradecane, and hexadecane.

According to an embodiment of the present invention, the non-aqueous organic solvent includes at least one selected from a group consisting of 1-hexadecene, toluene, xylene, chlorobenzoic acid, 1-octadecene, hexylamine, and bis-2-ethylhexylamine.

In accordance with another aspect of the present invention to achieve the object, there is provided a method for forming a conductive pattern including the steps of: preparing a metal ink composition; coating the metal ink composition on a circuit substrate by using an ink-jet nozzle; and performing heat-treatment for the metal ink composition on the circuit substrate, wherein the step of preparing the metal ink composition includes the steps of: synthesizing a cupper nano-particle; manufacturing a mixing solution by mixing the cupper nano-particle in the non-aqueous organic solvent; and adding at least one of neodecanoic acid, Naphthenic acid, and Linoleic acid to the mixing solution.

According to an embodiment of the present invention, the step of preparing the metal ink composition includes a step of forming the metal ink composition which includes the cupper nano-particle with 20 to 80 parts by weight, the non-aqueous organic solvent with 10 to 70 parts by weight, and the additive with 2 to 20 parts by weight.

According to an embodiment of the present invention, the step of coating the metal ink composition on the circuit substrate by using the ink-jet nozzle is achieved by repeatedly stacking the metal ink composition on a desired position where circuit lines are to be formed on the circuit substrate.

According to an embodiment of the present invention, the step of performing heat-treatment for the metal ink composition on the circuit substrate comprises a step of sintering the metal ink composition at a temperature of 200° C. or lower.

According to an embodiment of the present invention, the step of synthesizing the cupper nano-particle includes the steps of: manufacturing the mixing solution by adding Cu(NO3)2 of 0.5 mol to acid of 2 mol; adding butylamine of 1 mol to the mixing solution for dissociation of the Cu(NO3)2; heating and stirring the mixing solution at about temperature of 200° C. so as to perform reaction; and acquiring the cupper nano-particle from the mixing solution by using a centrifugation apparatus.

In accordance with further another aspect of the present invention to achieve the object, there is provided a conductive pattern formed by coating a conductive ink composition on a substrate, which includes a stacked structure of metal ink compositions which are stacked one on another with respect to oxide films interposed therebetween by repeatedly coating the conductive ink composition on the same position on the circuit substrate.

According to an embodiment of the present invention, the conductive pattern of claim 10, wherein the conductive ink composition includes: 20 to 80 parts by weight of cupper nano-particle; 10 to 70 parts by weight of non-aqueous organic solvent; and 2 to 20 parts by weight of at least one of additives which include neodecanoic acid, Naphthenic acid, and Linoleic acid, wherein the cupper nano-particle has a surface capped with any one dispersant of fatty acid and fatty amine.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

### DETAILED DESCRIPTION OF THE PREFERABLE EMBODIMENTS

The invention now will be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Hereinafter, a detailed description will be given of a metal ink composition and a method for forming metal lines formed by using the metal ink composition with reference to the accompanying drawings.

The metal ink composition in accordance with an embodiment of the present invention may be a material for formation of a certain metal line. For example, the metal ink composition may be a material for forming circuit lines with fine line widths on a circuit substrate like a PCB through an ink-jet printing scheme. The metal ink composition may be a lipophilic nano-ink.

The metal ink composition may include metal nano-particle, dispersant, non-aqueous organic solvent, and additive.

The metal nano-particle may be made using various kinds of metals. For example, the metal nano-particle may include at least one of Au, Ag, Ni, In, Zn, Ti, Cu, Cr, Ta, W, Pt, Fe, and Co. Herein, as the metal nano-particle becomes smaller, ink can be more easily discharged from inkjet nozzle. For example, the size of the metal nano-particle may be adjusted to be generally 50 nm or lower.

Also, in the present invention, since the non-aqueous organic solvent is used, metal nano-particle synthesized in non-aqueous solution may be used for compatibility with organic solvent. In one example, the metal nano-particle may have a composition of lipophilic metal nano-particle capped with fatty acid. A capping material like the fatty acid may be used as dispersant. The capped metal nano-particle may be manufactured by various methods that the present applicant has been already filed.

In one example, according to Korean Patent Application No. 10-2005-0072478, it is possible to acquire a metal nano-particle capped with such fatty acid as C11H22COOH, C17H33COOH, C9H19COOH, and C15H31COOH of being an alkanoic acid by using a cupper compound acting as a reducing agent.

In other example, according to Korean Patent Application No. 10-2005-0066936, it is possible to cap a fatty acid around metal nano-particle by performing heat treatment for metal alkanoate.

In other example, according to Korean Patent Application No. 10-2006-0064481, it is possible to acquire metal nano-particle capped with a fatty acid by using a metal salt as a metal catalyst of metals (e.g., Sn, Mg, and Fe), after dissociating a metal precursor by a fatty acid.

In other example, according to Korean Patent Application No. 10-2006-0098315, it is possible to acquire cupper nano-particle capped with a fatty acid either through dissociation and heating of a fatty acid having a cupper precursor inserted therein, or through addition of a reducing agent.

In other example, metal nano-particle capped with a fatty amine may also be used. In this case, as disclosed in Korean Patent Application No. 10-2006-0127697, a particle with two dispersants, that is, a particle with both fatty acid and fatty amine, may be used.

The above-mentioned methods are only for illustrative, and thus the present invention is not limited thereto. Alternatively, various methods may be used so as to prepare metal nano-particle capped with fatty acid.

The non-aqueous solvent may be used as organic solvent. For example, the organic solvent may include at least one selected from a group consisting of hexane, octane, decane, undecane, tetradecane, hexadecane, 1-hexadecene, 1-octadecene, hexylamine, and bis-2-ethylhexylamine.

The organic solvent affects a dry speed of ink lines discharged on a substrate, and thus it may be mixed to have a dry characteristic suitable for inkjet through a difference between a boiling point (BP) and a dew point (FP) for the solvent. For example, in adjusting the dry characteristic of ink, a solvent (e.g., 1-octadecene) with a high boiling point may cause delay of the dry speed, whereas a solvent (e.g., bis-2-ethylhexylamine) with a low boiling point may make the dry speed higher.

The additive may be used for improvement of dry characteristics of coated metal ink composition, when metal lines are formed using the metal ink composition. Metal compound of various types may be used as the additive for adjustment of the dry speed of the metal ink.

For example, according to American Society of Testing Materials (ASTM), a drier used in related industries may be classified into 6 types as described below.

### As for Liquid Paint Drier

class A: 2-ethyl haznoic acid
class B: Naphthenic acid
class C: Neodecanoic acid
class D: Tall oil Fatty acid
class E: any of above plus additives
class F: Other unidentified acids and Acid blends

Such a liquid paint drier may be an organic compound made by combining fatty acid of classes A to F types with a divalent or polyvalent metal selected from a group consisting of Pb, Co, Mg, Fe, Ba, Ca, Zr, Zn, Ce, V, Cu, and Bi.

Thus, preferably, a metal used for performing functions of the drier may be a metal with divalent or polyvalent ions. If the metal used for the above-mentioned dry function is a metal of a monovalent ion, the metal is difficult to react on double combination contained dispersant, which leads to a limited dry effect.

In consideration of the above-mentioned matters, the following materials may be used as the drier.

In one example, as for the drier, a metal compound made by combining the metals of Group-2 with at least one selected from 2-ethyl haxanoic acid, Naphthenic acid, neodecanoic acid, Tall oil Fatty acid may be used.

In other example, as for the drier, at least one selected from Copper(II) naphthenate, 2-Copper(II) 2-ethylhexanate, Co-naphthenate, Co-neodecanate, Co-2-ethylhexanate may be used.

In other example, as for the drier, resinate may be used.

The driers may be used individually or in combination with two or more of them. Meanwhile, in case of the metal ink composition, contents of the metal nano-particle, the organic solvent and the additive may be adjusted as follows.

The content of the metal nano-particle may be adjusted to have about 20 to 85 parts by weight. In case where the content of the metal nano-particle is less than 20 parts by weight, the content of metal is insufficient, and thus it is difficult to satisfy characteristics of lines. On the contrary, in case where the content of the metal nano-particle is greater than 85 parts by weight, viscosity of metal ink is high, and thus discharging of the ink may be not good.

More preferably, the content of the metal nano-particle may be adjusted to meet about 50 to 70 parts by weight. In this case, the metal ink composition may have a good flowing of ink while keeping the metal's content of a high concentration unchanged.

The content of the organic solvent may be adjusted to be 10 to 70 parts by weight. In this case, in order to increase the concentration of metal within the desired metal line to be formed by using the metal ink, the content of the organic solvent may be adjusted to be contained as little as possible. For example, in case where the content of the organic solvent is equal to or less than 10 parts by weight, a dry speed of the inkjet is high, which causes problems, such as blocking of the nozzle, and non-guarantee of distribution stability of particles. On the contrary, the content of the organic solvent is equal to or higher than 70 parts by weight, desired metal lines to be formed may have a reduced reliability of electric conductivity.

The content of the additive may be adjusted to be 2 to 7 parts by weight. In case where the content of the additive is less than 2 parts by weight, the content of the additive is not much, and thus the additive has a difficulty acting as a drier. On the contrary, in case where the content of the additive is greater than 7 parts by weight, characteristics of the drier are excessive, and thus the dry speed of the metal ink composition may be significantly high at the time of forming the metal lines.

As described above, the metal ink composition of the present invention may include a metal nano particle capped by a dispersant, an organic solvent, and an additive for improving dry characteristics in drying the metal ink compositions. The additive may be adjusted to have a content suitable for the dry speed of the metal ink compositions, so that it is possible to prevent cracking of the metal lines at the time of formation of the metal lines. Thus, the metal ink compositions of the present invention can form metal lines with no crack therein.

Continuously, a detailed description will be given of a method for manufacturing metal ink compositions and a method for forming the metal lines by using the manufactured metal ink compositions. Herein, the repeated description for the above-mentioned metal ink composition will be omitted, or simplified.

### Manufacturing Example

### a) One Example for Manufacturing a Cupper Nano-Particle

A mixing solution was manufactured by adding Cu(NO3)2 of 0.5 mol to oleic acid of 2 mol, and then butylamine of 1 mol for disassociation of Cu(NO3)2 was added to the mixing solution. In this case, a color of the mixing solution was almost a transparent green-based color. The mixing solution was heated at about 200° C. and stirred for its reaction. In this case, reduction reaction occurred within the mixing solution, and the color of the mixing solution became brown and then, the metal nano-particle was formed on wall surfaces of a glass reactor. After the reaction processes were performed during about more than two hours, a mixture of acetone and methanol of being a polar solution was used for re-precipitation of the formed nano-particle. And then, by using a centrifugation apparatus, a cupper nano-particle was obtained from the mixing solution.

### b) One Example for Manufacturing an Ag Nano-Particle

A toluene solvent of 300 g was added to AgNO3 of 170 g and Cu(acac)2 of 20 g to thereby form a mixing solution. Butylamine of 100 g was added to the mixing solution, and the resultant solution was agitated. And then, Palmitic Acid of 50 g was more added to the mixing solution. The mixing solution was heated at a temperature of 110° C., and agitated for two hours. In the agitated state, the mixing solution was cooled in a room temperature of 28° C. And then, Ag nano-particle was formed and a methanol was added to the formed Ag nano-particle. Then, centrifugation for Ag nan-particle with the methanol was performed so that only Ag nano-particle from the Ag nano-particle with the methanol was selectively precipitated and separated. In this way, it was possible to a metal nano-particle of 90 g whose particles are uniformly distributed at a size of 4 nm.

### c) One Example for Manufacturing Metal Ink and Method for Forming Metal Lines by Using the Same

A metal ink composition was manufactured by being mixed with the organic solvent, driers, metal nano-particles whose contents are listed in Table 1 below. The metal ink composition manufactured in this way was used to thereby form metal lines in an ink-jet printing. For example, an ink-jet nozzle was prepared which can discharge the metal ink composition manufactured in this way, and by the ink-jet nozzle, the metal ink composition was printed on a desired portion where metal lines are to be formed on a PCB. Herein, for the desired portion of the metal lines, printing was performed as many as number of times listed in Table 1 below, so that it was possible to improve characteristics of metal lines. And then, thermal treatment (sintering process) was performed for the resultant metal line to thereby form finally metal lines.

Table 1 below shows details of the method for manufacturing metal ink and the method for forming metal lines.

TABLE 1

| | | | | | | | | Number | Oc- | | |
|---|---|---|---|---|---|---|---|---|---|---|---|
| | | | | | | | | of times | currence | | Post- |
| | Metal | | | | Cu- | | | for | of crack | Printing | sintering |
| | nano- | Oleic | | Co- | neodecanoic | Co- | Occurrence | repeated | during | thickness | thickness |
| | particle | acid | Tetradecane | Naphthenate | acid | Octonate | of crack | printing | sintering | (μm) | (μm) |
| Experimental | Ag | 10.8 wt % | 23.2 wt % | 6 wt % | | | no | 6 | no | 12 | 8 |
| example 1 | 60 wt % | | | | | | | | | | |
| Experimental | Ag | 10.8 wt % | 22.2 wt % | | 7 wt % | | no | 6 | no | 12 | 8 |
| example 2 | 60 wt % | | | | | | | | | | |
| Experimental | Ag | 10.8 wt % | 19.2 wt % | | | 10 wt % | no | 3 | no | 10 | 3 |
| example 3 | 60 wt % | | | | | | | | | | |
| Experimental | Ag | 10 wt % | 47 wt % | 3 wt % | | | no | 6 | no | 12 | 7 |
| example 4 | 40 wt % | | | | | | | | | | |
| Experimental | Cu | 10 wt % | 43 wt % | | 7 wt % | | no | 6 | no | 12 | 7 |
| example 5 | 40 wt % | | | | | | | | | | |
| Comparative | Cu | 10 wt % | 50 wt % | | | | yes | 6 | yes | 12 | 7 |
| example 1 | 40 wt % | | | | | | | | | | |
| Comparative | Ag | 10.8 wt % | 29.2 wt % | 50 wt % | | | yes | 6 | yes | 12 | 7 |
| example 2 | 60 wt % | | | | | | | | | | |

As listed in Table 1, according to the present invention, it was clear that there was no crack in metal lines formed of metal ink containing additives, such as Co-naphtahenate, Cu-neodecanoic acid, and Co-Octonate in comparison with metal lines formed of metal ink containing no additives as described above. This means that the driers were for preventing crack of discharged metal ink by improving dry characteristics of the metal ink.

### d) Another Example for Manufacturing Metal Ink and Method for Forming Metal Lines Using the Same

A metal ink composition was manufactured by being mixed with the organic solvent, driers, metal nano-particle whose contents are listed in Table 2 below. Herein, the metal ink may be a cupper metal ink composition. And, it was possible to form metal lines in an ink-jet printing scheme by using the metal ink composition manufactured by the above-mentioned way.

For example, an ink-jet nozzle was prepared which can discharge the metal ink composition manufactured in this way, and by the ink-jet nozzle, the metal ink composition was printed on a desired portion where metal lines are to be formed on a PCB. Herein, for the desired portion of the metal lines, printing was performed as many as number of times listed in Table 2 below, so that it was possible to improve characteristics of metal lines. And then, thermal treatment (sintering process) was performed for the resultant metal line to thereby form finally metal lines. Table 2 shows details of a method for manufacturing metal ink and a method for forming metal lines.

TABLE 2

| | | | | | | | | Number | Oc- | | |
|---|---|---|---|---|---|---|---|---|---|---|---|
| | | | | | | | | of times | currence | | Post- |
| | Cupper | | | | | | | for | of crack | Printing | sintering |
| | nano- | Oleic | | | Neodecanoic | Naphthenoic | Occurrence | repeated | during | thickness | thickness |
| | particle | acid | Tetradecane | Octadecene | acid | acid | of crack | printing | sintering | (μm) | (μm) |
| Experimental | 40 wt % | 10 wt % | 43 wt % | | 7 wt % | | no | 15 | no | 40 | 16 |
| example 1 | | | | | | | | | | | |
| Experimental | 40 wt % | 10 wt % | 40 wt % | | 10 wt % | | no | 8 | no | 18 | 8 |
| example 2 | | | | | | | | | | | |
| Experimental | 40 wt % | 10 wt % | 40 wt % | | | 10 wt % | no | 3 | no | 10 | 3 |
| example 3 | | | | | | | | | | | |
| Experimental | 40 wt % | 10 wt % | 43 wt % | | | 7 wt % | no | 6 | no | 12 | 7 |
| example 4 | | | | | | | | | | | |
| Experimental | 40 wt % | 10 wt % | 47 wt % | | 3 wt % | | no | 6 | no | 12 | 7 |
| example 5 | | | | | | | | | | | |
| Comparative | 40 wt % | 10 wt % | 50 wt % | | | | yes | 6 | yes | 12 | 7 |
| example 1 | | | | | | | | | | | |
| Comparative | 40 wt % | 10 wt % | | 50 wt % | | | yes | 6 | yes | 12 | 7 |
| example 2 | | | | | | | | | | | |

As listed in Table 2, according to the present invention, it was clear that there was no crack in metal lines formed of metal ink containing at least one selected from cupper nano-particle, Co-naphtahenate, Cu-neodecanoic acid, and Co-Octonate in comparison with metal lines formed of metal ink containing no additives as described above. This means that the driers were for preventing crack of discharged metal ink by improving dry characteristics of the metal ink.

Meanwhile, in a process of performing repeated printing through the ink-nozzle, it was possible to form a certain thin film on surfaces of the metal ink coated on a circuit substrate. For example, surfaces of the metal ink exposed to the outside react with oxygen O2 within exterior air to thereby form a metal oxide layer in a film form. The metal oxide layer may be formed on surfaces of each of metal ink compositions repeatedly coated by the ink-jet nozzle. Therefore, the metal lines formed by repeated printing of the metal ink compositions may have a stacking structure of metal ink compositions which are stacked one on another with respect to oxide films interposed therebetween. The oxide films may perform a function of suppressing occurrence of crack in the metal ink.

As described above, the metal ink composition of the present invention is made by using dispersant having double combination for metal nano particles, driers selectively reacting on the double combination, so that when the metal lines are formed, the contents of the driers can be adjusted so as to control a dry speed of the metal ink. Thus, in the method of forming the metal lines according to the present invention, it is possible to reduce occurrence of crack in the metal lines by improving reaction of the driers.

According to the present invention, metal ink compositions may include metal nano-particle capped by dispersant, organic solvent, and additives used for improvement of dry characteristics of the metal ink compositions. Herein, the additives have contents adjusted to control a dry speed of the metal ink compositions, so that it is possible to prevent occurrence of crack in the metal lines at the time of forming the metal lines. Thus, by the metal ink compositions of the present invention, it is possible to form metal lines with no crack.

In a method for forming metal lines of the present invention, metal lines are formed using metal ink compositions containing additives for improvement of dry characteristics, so that when the metal lines are formed, dry characteristics of the metal ink compositions are improved, which results in formation of metal lines without crack.

Conductive pattern formed by the metal ink compositions of the present invention are formed by repeated coating of the conductive ink compositions on the same portion of a circuit substrate. Additionally, the conductive patterns may have a stacked structure where oxide films are interposed between metal ink compositions stacked one on another. The oxide films may be used as films for keeping the shape of the metal ink compositions coated on the circuit substrate unchanged. Thus, the metal ink compositions of the present invention can have no occurrence of crack therein.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A metal ink composition for forming a conductive pattern comprising:
20 to 80 parts by weight of cupper nano-particle;
10 to 70 parts by weight of non-aqueous organic solvent; and
2 to 20 parts by weight of at least one selected from additives which include neodecanoic acid, Naphthenic acid, and Linoleic acid.

2. The metal ink composition of claim 1, wherein the cupper nano-particle has a surface capped with at least one dispersant selected from fatty acid and fatty amine.

3. The metal ink composition of claim 1, wherein the non-aqueous organic solvent includes at least one selected from a group consisting of hexane, octane, decane, tetradecane, and hexadecane.

4. The metal ink composition of claim 1, wherein the non-aqueous organic solvent includes at least one selected from a group consisting of 1-hexadecene, toluene, xylene, chlorobenzoic acid, 1-octadecene, hexylamine, and bis-2-ethylhexylamine.

5. A method for forming a conductive pattern comprising:
preparing a metal ink composition;
coating the metal ink composition on a circuit substrate by using an ink-jet nozzle; and
performing heat-treatment for the metal ink composition on the circuit substrate,
wherein preparing the metal ink composition comprises:
synthesizing a cupper nano-particle;
manufacturing a mixing solution by mixing the cupper nano-particle in the non-aqueous organic solvent; and
adding at least one of neodecanoic acid, Naphthenic acid, and Linoleic acid to the mixing solution.

6. The method of claim 5, wherein preparing the metal ink composition comprises forming the metal ink composition which includes the cupper nano-particle with 20 to 80 parts by weight, the non-aqueous organic solvent with 10 to 70 parts by weight, and the additive with 2 to 20 parts by weight.

7. The method of claim 5, wherein coating the metal ink composition on the circuit substrate by using the ink-jet nozzle is achieved by repeatedly stacking the metal ink composition on a desired position where circuit lines are to be formed on the circuit substrate.

8. The method of claim 5, wherein performing heat-treatment for the metal ink composition on the circuit substrate comprises sintering the metal ink composition at a temperature of 200° C. or lower.

9. The method of claim 5, wherein synthesizing the cupper nano-particle comprises:
manufacturing the mixing solution by adding Cu(NO3)2 of 0.5 mol to acid of 2 mol;
adding butylamine of 1 mol to the mixing solution for dissociation of the Cu(NO3)2;
heating and stirring the mixing solution at about temperature of 200° C. so as to perform reaction; and
acquiring the cupper nano-particle from the mixing solution by using a centrifugation apparatus.

10. A conductive pattern formed by coating a conductive ink composition on a substrate comprising, a stacked structure of metal ink compositions which are stacked one on another with respect to oxide films interposed therebetween by repeatedly coating the conductive ink composition on the same position on the circuit substrate.

11. The conductive pattern of claim 10, wherein the conductive ink composition comprises:
20 to 80 parts by weight of cupper nano-particle;
10 to 70 parts by weight of non-aqueous organic solvent; and
2 to 20 parts by weight of at least one of additives which include neodecanoic acid, Naphthenic acid, and Linoleic acid,
wherein the cupper nano-particle has a surface capped with any one dispersant of fatty acid and fatty amine.
